(19) United States
(12) Patent Application Publication
(10) Pub. No.: US 2013/0115753 A1
(43) Pub. Date: May 9, 2013

(54) METHOD OF MANUFACTURING THIN FILM-BONDED SUBSTRATE

(71) Applicant: Samsung Corning Precision Materials Co., Ltd., Gyeongsangbuk-do (KR)

(72) Inventors: Sungwoo EO, ChungCheongNam-Do (KR); Kyoungjun KIM, ChungCheongNam-Do (KR)

(73) Assignee: SAMSUNG CORNING PRECISION MATERIALS CO., LTD., Gyeongsangbuk-do (KR)

(21) Appl. No.: 13/668,831

(22) Filed: Nov. 5, 2012

(30) Foreign Application Priority Data
Nov. 4, 2011 (KR) 10-2011-0114536

(51) Int. Cl. H01L 21/301

(52) U.S. Cl. 438/458; 257/E21.568

(57) ABSTRACT

A method of manufacturing a thin film-bonded substrate in which a high-quality gallium nitride (GaN) thin film can be transferred. The method includes implanting ions into a first

GaN substrate from a Ga surface thereof and thereby forming a first ion implantation layer, bonding a first heterogeneous substrate onto the Ga surface of the first GaN substrate, cleaving the first GaN substrate along the first ion implantation layer and thereby leaving a second GaN substrate on the first heterogeneous substrate, implanting ions into the second GaN substrate from an N surface thereof and thereby forming a second ion implantation layer, bonding a second heterogeneous substrate onto the N surface of the second GaN substrate, and cleaving the second GaN substrate along the second ion implantation layer and thereby leaving a GaN thin film.

### CROSS REFERENCE TO RELATED APPLICATION

The present application claims priority from Korean Patent Application Number 10-2011-0114536 filed on Nov. 4, 2011, the entire contents of which application are incorporated herein for all purposes by this reference.

### BACKGROUND OF THE INVENTION

1. Field of the Invention

The present invention relates to a method of manufacturing a thin film-bonded substrate, and more particularly, to a method of manufacturing a thin film-bonded substrate in which a high-quality gallium nitride (GaN) thin film can be transferred.

2. Description of Related Art

The performance and longevity of a semiconductor device, such as a laser diode (LD) or a light-emitting diode (LED), are determined by a variety of components that constitute the corresponding device, and in particular, by a base substrate on which the device is stacked. Accordingly, while a variety of approaches which are intended to manufacture a high-quality semiconductor substrate has been introduced, interest in group III-V compound semiconductor substrates is increasing.

Here, gallium nitride (GaN) substrates can be regarded as a representative example of group III-V compound semiconductor substrates. While GaN substrates are suitable for semiconductor devices together with gallium arsenide (GaAs) substrates, indium phosphide (InP) substrates, and the like, the manufacturing cost thereof is much more expensive than those of GaAs substrates and InP substrates. Accordingly, the manufacturing cost of semiconductor devices which use GaN substrates becomes very high. This is because a method of manufacturing GaN substrates is different from methods of manufacturing GaAs substrates and InP substrates.

Specifically, for GaAs substrates and InP substrates, the growth rate of crystal is rapid since crystalline growth is carried out by a liquid method, such as the Bridgman method or the Czochralski method. It is therefore possible to easily produce a large GaAs or InP bulk crystal having a thickness of 200 nm or greater in a crystal growth time of, for example, about 100 hours. Accordingly, a large number of, for example, 100 or more GaAs or InP substrates having a thickness ranging from 200 μm to 400 μm can be cleaved from the large GaAs or InP bulk crystal.

In contrast, as for GaN substrates, the growth rate of crystal is slow since crystalline growth is carried out by a vapor deposition method, such as hydride vapor phase epitaxy (HVPE) or metal organic chemical vapor deposition (MOCVD). For example, a GaN bulk crystal can be produced with a thickness of only about 10 mm for a crystal growth time of 100 hours. When the thickness of the crystal is in that range, only a small number of GaN substrates, for example, 10 GaN substrates having a thickness ranging from 200 μm to 400 μm can be cleaved from that crystal.

However, when the thickness of a GaN film to be cleaved from the GaN bulk crystal is reduced in order to increase the number of cleaved GaN substrates, the mechanical strength of the cleaved substrates decreases to the extent that the cleaved substrates cannot make a self-supporting substrate. Therefore, a method for reinforcing the strength of a GaN thin film layer that is cleaved from the GaN bulk crystal was required.

As the method for reinforcing a GaN thin film layer of the related art, there is a method of manufacturing a substrate (hereinafter, referred to as a bonded substrate) in which a GaN thin film layer is bonded to a heterogeneous substrate which has a different chemical composition from GaN, for example, a Si substrate. However, the bonded substrate which is manufactured by the method of manufacturing a bonded substrate of the related art has a problem in that the GaN thin film layer easily peels off the heterogeneous substrate during the process of stacking a semiconductor layer on the GaN thin film layer.

In order to overcome this problem, a method for cleaving a thin film layer via ion implantation was proposed. This method manufactures a bonded substrate in which a GaN thin film layer is bonded to a heterogeneous substrate by forming an ion implantation layer, i.e. a damage layer, by irradiating one surface of a GaN bulk crystal which is supposed to be bonded to the heterogeneous substrate with hydrogen, helium or nitrogen ions; directly bonding the GaN bulk crystal in which the damage layer is formed to the heterogeneous substrate; heat-treating the resultant structure; and then cleaving the GaN bulk crystal on the damage layer.

Since semiconductor substrates made of a nitride, such as GaN, employ a growth method using a deposition technology, defects such as dislocations and different densities are more popular in the lower layer (nitrogen (N) surface) than in the upper layer (gallium (Ga) surface). Here, sequential transfer must be carried out using the lower layer which has more defects. This is because the Ga surface must be exposed upward during the transfer. Owing to this problem, the transfer of a high-quality GaN thin film is limited in the related art.

The information disclosed in the Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of manufacturing a thin film-bonded substrate in which a high-quality gallium nitride (GaN) thin film can be transferred.

In an aspect of the present invention, provided is a method of manufacturing a thin film-bonded substrate. The method includes the following steps of: implanting ions into a first GaN substrate to a predetermined depth from a Ga surface thereof and thereby forming a first ion implantation layer in the first GaN substrate; bonding a first heterogeneous substrate onto the Ga surface of the first GaN substrate, the first heterogeneous substrate having a different chemical composition from the first GaN substrate; cleaving the first GaN substrate along the first ion implantation layer and thereby leaving a second GaN substrate on the first heterogeneous substrate, the second GaN substrate being separated out of the first GaN substrate; implanting ions into the second GaN substrate to a predetermined depth from an N surface thereof and thereby forming a second ion implantation layer in the second GaN substrate; bonding a second heterogeneous substrate onto the N surface of the second GaN substrate, the second heterogeneous substrate having a different composition from the second GaN substrate; and cleaving the second GaN substrate along the second ion implantation layer and thereby leaving a GaN thin film on the second heterogeneous substrate, the GaN thin film being separated out of the second GaN substrate.

In an embodiment of the invention, the first and second heterogeneous substrates may be made of one selected from the delegate group consisting of Si, AlN, GaAs, AlGaN and InP.

In an embodiment of the invention, the step of forming the first ion implantation layer may form the first ion implantation layer into a depth ranging from 0.1 μm to 2 μm from the Ga surface of the first GaN substrate.

Here, the ions implanted into the first GaN substrate and the ions implanted into the second GaN substrate may be ions of one selected from the group consisting of hydrogen, helium and nitrogen.

In an embodiment of the invention, at least one of the step of bonding the first heterogeneous substrate onto the Ga surface of the first GaN substrate and the step of bonding the second heterogeneous substrate onto the N surface of the second GaN substrate may be surface activated bonding or fusion bonding.

In an embodiment of the invention, the step of cleaving the first GaN substrate along the first ion implantation layer may cleave the first GaN substrate by heat-treating or cutting the first ion implantation layer.

In an embodiment of the invention, the step of cleaving the second GaN substrate along the second ion implantation layer may cleave the second GaN substrate by heat-treating or cutting the second ion implantation layer.

According to embodiments of the invention, a high-quality layer of a self-standing GaN substrate can be used for transferring a thin film.

In addition, in the self-standing GaN substrate, the upper layer (Ga surface) which can be more easily surface-processed than the lower layer (N surface) is processed via mechanical processing or chemical processing. It is therefore efficient at ensuring flatness and uniformity after the transfer.

Furthermore, a thin GaN substrate having the thickness of a film is finally used in the process of forming the GaN thin film by adding the process of cleaving the GaN substrate instead of forming the GaN thin film directly from a thick self-standing GaN substrate. This accordingly is less influenced by the total thickness variation (TTV) and bowing of the self-standing GaN substrate which have been regarded as factors that cause the transfer of the GaN layer to be unreliable in the related art.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a flowchart sequentially showing the processes of a method of manufacturing a thin film-bonded substrate according to an exemplary embodiment of the invention; and

FIG. 2 to FIG. 9 are schematic views sequentially showing the processes of the method of manufacturing a thin film-bonded substrate according to an exemplary embodiment of the invention.

### DETAILED DESCRIPTION OF THE INVENTION

Reference will now be made in detail to a method of manufacturing a thin film-bonded substrate according to an exemplary embodiment of the invention, examples of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

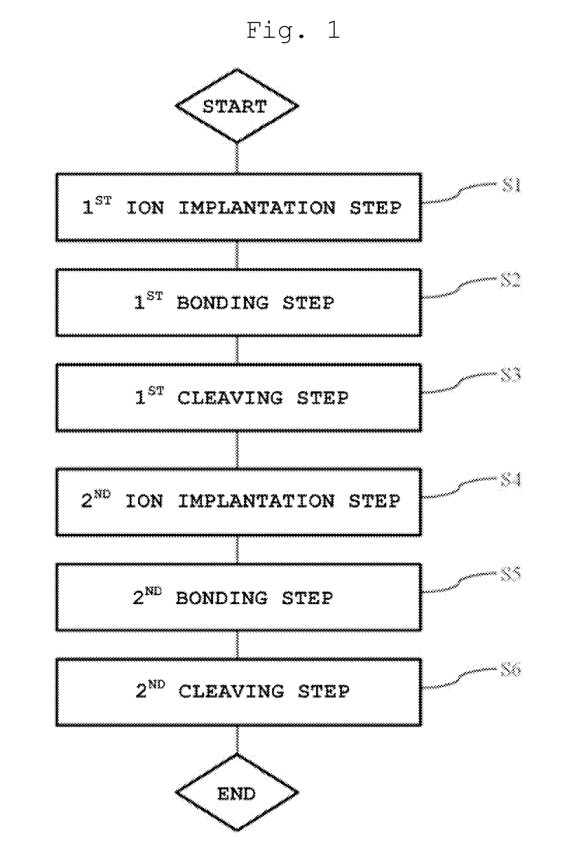

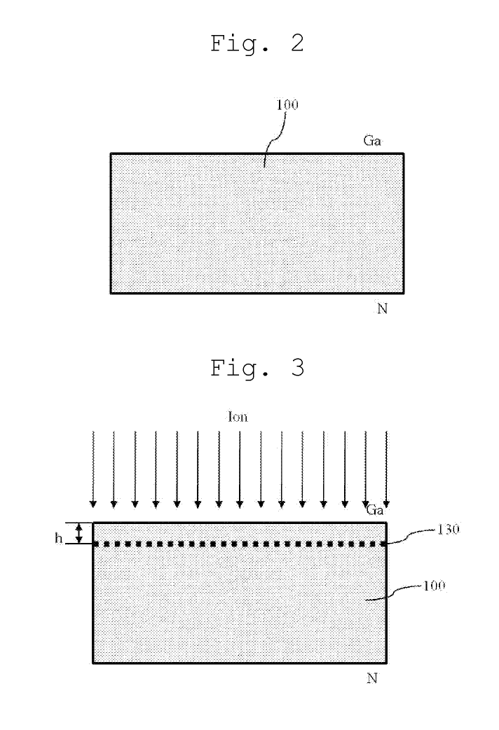

Referring to FIG. 1 together with FIG. 2 to FIG. 9, the method of manufacturing a thin film-bonded substrate according to an exemplary embodiment of the invention is a method of manufacturing a thin film-bonded substrate 10 by bonding a gallium nitride (GaN) substrate 111 with a heterogeneous substrate 102 having a different chemical composition from the GaN substrate 111 in order to reinforce the strength of the GaN substrate 111. The method includes a first ion implantation step S1, a first bonding step S2, a first cleaving step S3, a second ion implantation step S4, a second bonding step S5 and a second cleaving step S6.

First, as shown in FIG. 2 and FIG. 3, the first ion implantation step S1 is the step of forming a first ion implantation layer 130 by implanting ions into a first GaN substrate 100 to a predetermined depth from the gallium (Ga) surface thereof. The first GaN substrate 100 can be grown using a growth method such as hydride vapor phase epitaxy (HVPE). It is possible to polish the surface of the first GaN substrate 100 before ions are implanted into the GaN surface of the first GaN substrate 100. That is, the Ga surface of the first GaN surface can be formed as a mirror surface by polishing the Ga surface of the first GaN substrate 100. Here, the nitrogen (N) surface is present on the opposite face of the substrate 100.

At the first ion implantation step S1, ions are implanted into the first GaN substrate 100 from a position that is in front of the Ga surface of the first GaN substrate 100. Ions that are implanted at this step can be ions of one selected from among hydrogen (H), helium (He) or nitrogen (N). In addition, it is possible to implant ions into the first GaN substrate 100 from the Ga surface thereof to a depth “h,” for example, a depth ranging from 0.1 μm to 2 μm, thereby forming the first ion implantation layer 130 at that position. In the subsequent process, the first ion implantation layer 130 acts as an interface for a cleaving process in which a second GaN substrate 200 having a thickness “h” is to be formed.

The ion implantation step S3 like this can be carried out using a separate ion implantation apparatus (not shown).

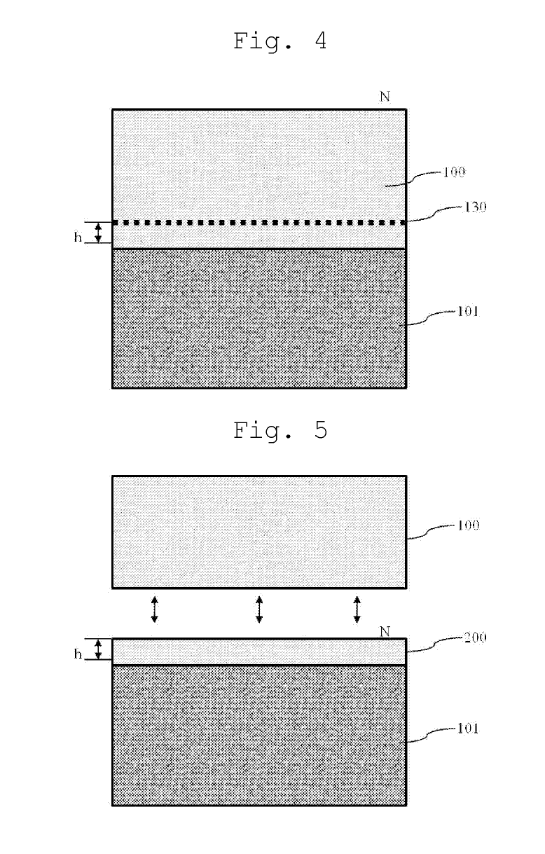

In sequence, as shown in FIG. 4, the first bonding step S2 is the step of bonding a first heterogeneous substrate 101 onto the Ga surface of the first GaN substrate 100. Here, the process of bonding the first GaN substrate 100 and the first heterogeneous substrate 101 can be implemented as surface activated bonding or fusion bonding on the premise that the bonding is uniformly performed at low temperature. Here, the surface activated bonding is a process in which bonding surfaces are activated by being exposed to plasma before being bonded to each other. The fusion bonding is a process in which respective surfaces that have been cleaned are bonded to each other via pressurization and heating. However, in this embodiment of the present invention, the bonding between the first GaN substrate 100 and the first heterogeneous substrate 101 is not limited to a specific method, since the first GaN substrate 100 and the first heterogeneous substrate 101 can be bonded to each other by other methods.

Here, the first heterogeneous substrate 101 can be implemented as a substrate of one selected from the candidate group consisting of silicon (Si), aluminum nitride (AlN), gallium arsenide (GaAs), aluminum gallium nitride (AlGaN) and indium phosphide (InP).

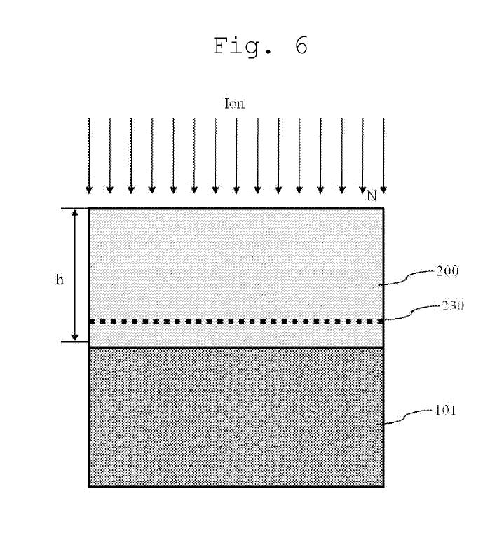

Afterwards, as shown in FIG. 5, the first cleaving step S3 is the step of cleaving the first GaN substrate 100 along a boundary surface, i.e. the first ion implantation layer 130 that is formed inside the first GaN substrate 100, thereby leaving a second GaN substrate 200 which is separated out of the first GaN substrate on the first heterogeneous substrate 101. The first cleaving step S3 can use heat treatment or cutting in order to cleave the first GaN substrate 100. Here, the heat treatment can be available when the first ion implantation layer 130 is formed at a relatively shallow position inside the first GaN substrate 100. The heat treatment is a process that has high precision, is easy to carry out, and can reliably cleave the first GaN substrate 100. When the first GaN substrate 100 and the first heterogeneous substrate 101 which are bonded to each other are heat-treated, the first ion implantation layer 130 is embrittled, and the first GaN substrate 100 is cleaved along the embrittled portion, thereby leaving the second GaN substrate 200 having a thickness or height “h.” Here, a temperature at which the heat treatment is carried out can be adjusted in the range from 300° C. to 600° C. depending on the characteristics of ions that were implanted. In addition, the cutting can be available when the ion implantation layer 130 is formed at a relatively deep position. The cutting is also a method that has high precision, is easy to carry out, and can reliably cleave the first GaN substrate 100.

In sequence, as shown in FIG. 6, the second ion implantation step S4 is the step of forming a second ion implantation layer 230 by implanting ions into the second GaN substrate 200 having the thickness or height “h” which is formed on the first heterogeneous substrate 101 to a predetermined depth from the nitrogen (N) surface thereof. The N surface of the second GaN substrate 200 can also be polished in order to increase the strength of bonding with the second heterogeneous substrate 102. Here, it is possible to control the maximum surface roughness Rₘₐₓ of the bonding surface, i.e. the N surface of the second GaN substrate 200, by polishing it while controlling the average surface roughness Rₐ of the bonding surface by carrying out etching after the polishing. It is preferred that the maximum surface roughness Rₘₐₓ of the bonding surface be controlled so as to be 10 μm or less and the average surface roughness Rₐ of bonding surface be controlled so as to be 1 nm or less.

At the second ion implantation step S4, ions are implanted into the second GaN substrate 200 from a position that is in front of the N surface of the second GaN substrate 200. Ions that are implanted at this step can be the same as those of the first ion implantation step S1. Specifically, ions that are implanted at the second ion implantation step S4 can be ions of one selected from among H, He or N. It must be that the depth of ions that are implanted is shallower than the thickness “h” of the second GaN substrate 200. That is, ions are implanted at a position that is shallower than the thickness “h,” thereby forming the second ion implantation layer 230 at that position. In the subsequent process, the second ion implantation layer 230 acts as an interface for a cleaving process in which the GaN thin film 111 is to be formed.

The second ion implantation step S4 as described above can be carried out using a separate ion implantation apparatus (not shown) like the first ion implantation step S1.

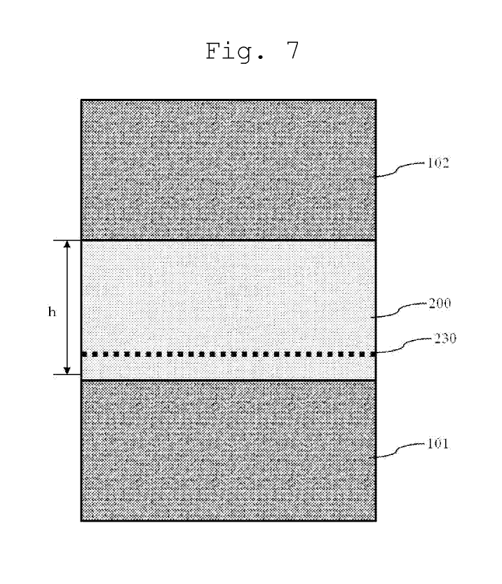

Afterwards, as shown in FIG. 7, the second bonding step S5 is the step of bonding a second heterogeneous substrate 102 onto the N surface of the second GaN substrate 200. The second heterogeneous substrate 102 is a substrate that has a different chemical composition from the second GaN substrate 200. Prior to the second bonding step S5, the N surface of the second GaN substrate 200 can be etched using chlorine (Cl) gas and the surface of the second heterogeneous substrate 102 can be etched using argon (Ar) gas in order to increase the bonding strength between the second GaN substrate 200 and the second heterogeneous substrate 102 which are to be bonded to each other.

After the respective bonding surfaces have been made clean by etching them, the second heterogeneous substrate 102 is bonded onto the N surface of the second GaN substrate 200 at the second bonding step S5. Like the bonding between the first GaN substrate 100 and the first heterogeneous substrate 101 at the first bonding step S2, the bonding between the second GaN substrate 200 and the second heterogeneous substrate 102 can be implemented as surface activated bonding or fusion bonding on the premise that the bonding is uniformly performed at low temperature. However, the present invention is not intended to be limited thereto.

In addition, the second heterogeneous substrate 102 can also be implemented as a substrate of one selected from the candidate group consisting of Si, AlN, GaAs, AlGaN and InP.

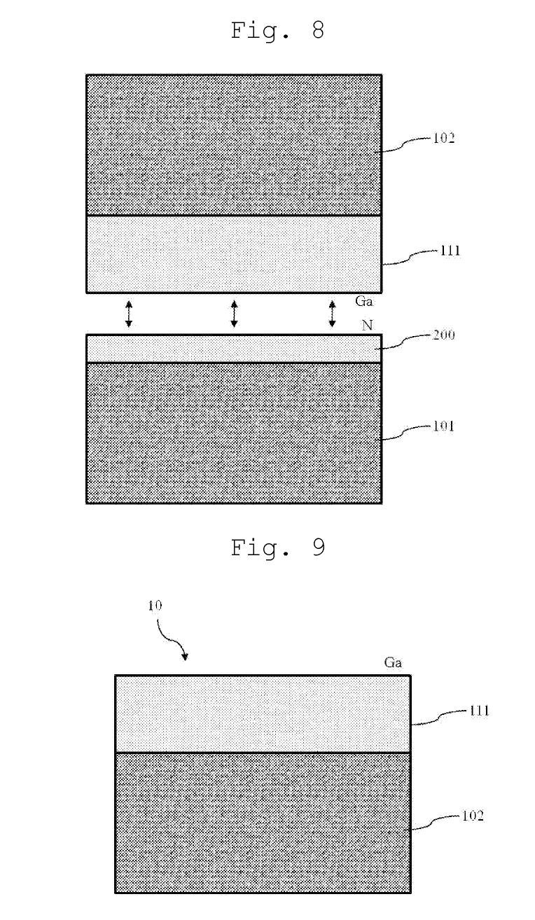

Finally, as shown in FIG. 8, the second cleaving step S6 is the step of cleaving the second GaN substrate 200 along the second ion implantation layer 230 which is formed inside the second GaN substrate 200, thereby leaving the GaN thin film 111 which is separated out of the second GaN substrate 200 on the second heterogeneous substrate 102. The second cleaving step S6 can be carried out by the same process as the first cleaving step S3. That is, the second cleaving step S6 can use heat treatment or cutting in order to cleave the second GaN substrate 200.

When the second GaN substrate 200 is cleaved via the heat treatment or the cutting, the manufacturing of the thin film-bonded substrate 10 which includes the second heterogeneous substrate 102 and the GaN thin film 111 is completed, as shown in FIG. 9. The GaN thin film 111 is separated out of the second GaN substrate 200, with the Ga surface thereof being exposed.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of manufacturing a thin film-bonded substrate, comprising:
implanting ions into a first GaN substrate to a predetermined depth from a Ga surface thereof and thereby forming a first ion implantation layer in the first GaN substrate;
bonding a first heterogeneous substrate onto the Ga surface of the first GaN substrate, the first heterogeneous substrate having a different chemical composition from the first GaN substrate;
cleaving the first GaN substrate along the first ion implantation layer and thereby leaving a second GaN substrate on the first heterogeneous substrate, the second GaN substrate being separated out of the first GaN substrate;
implanting ions into the second GaN substrate to a predetermined depth from an N surface thereof and thereby forming a second ion implantation layer in the second GaN substrate;
bonding a second heterogeneous substrate onto the N surface of the second GaN substrate, the second heterogeneous substrate having a different composition from the second GaN substrate; and
cleaving the second GaN substrate along the second ion implantation layer and thereby leaving a GaN thin film on the second heterogeneous substrate, the GaN thin film being separated out of the second GaN substrate.

2. The method of claim 1, wherein the first and second heterogeneous substrates comprise one selected from the delegate group consisting of Si, AlN, GaAs, AlGaN and InP.

3. The method of claim 1, wherein forming the first ion implantation layer comprises forming the first ion implantation layer into a depth ranging from 0.1 μm to 2 μm from the Ga surface of the first GaN substrate.

4. The method of claim 3, wherein the ions implanted into the first GaN substrate and the ions implanted into the second GaN substrate comprise ions of one selected from the group consisting of hydrogen, helium and nitrogen.

5. The method of claim 1, wherein at least one of bonding the first heterogeneous substrate onto the Ga surface of the first GaN substrate and bonding the second heterogeneous substrate onto the N surface of the second GaN substrate comprises surface activated bonding or fusion bonding.

6. The method of claim 1, wherein cleaving the first GaN substrate along the first ion implantation layer comprises heat-treating or cutting the first ion implantation layer.

7. The method of claim 1, wherein cleaving the second GaN substrate along the second ion implantation layer comprises heat-treating or cutting the second ion implantation layer.
